(19) United States
(12) Patent Application Publication
(10) Pub. No.: US 2018/0323295 A1
(43) Pub. Date: Nov. 8, 2018

(54) SEMICONDUCTOR DEVICE AND MANUFACTURING METHOD THEREOF

(71) Applicant: ADVANTEST CORPORATION, Tokyo (JP)

(72) Inventors: Jun'ichi OKAYASU, Tokyo (JP); Yoshiaki ABE, Tokyo (JP); Takuya OIZUMI, Tokyo (JP); Takahiro YASHIRO, Tokyo (JP)

(21) Appl. No.: 16/031,493

(22) Filed: Jul. 10, 2018

Related U.S. Application Data
(63) Continuation of application No. PCT/JP2017/004207, filed on Feb. 6, 2017.

(30) Foreign Application Priority Data
Feb. 29, 2016 (JP) 2016-036774

(51) Int. Cl. H01L 29/778; H01L 29/20; H01L 29/16; H01L 29/66; H01L 21/02; H01L 21/768

(52) U.S. Cl. CPC H01L 29/778; H01L 29/2003; H01L 29/1608; B08B 3/12; H01L 21/02378; H01L 21/02458; H01L 21/76804; H01L 29/66462

(57) ABSTRACT

In a semiconductor device, an epitaxial substrate includes a SiC (silicon carbide) substrate and a GaN (gallium nitride) epitaxial layer formed on the SiC substrate. A multi-layer wiring structure is formed on the front-face side of the epitaxial substrate, and includes at least one metal wiring layer and an organic interlayer dielectric. A back-face metal layer is formed on the back face of the epitaxial substrate. At least one via hole is formed in the epitaxial substrate, and is configured to provide a connection between the multi-layer wiring structure and the back-face metal layer.

### CROSS REFERENCE TO RELATED APPLICATION(S)

This application is a continuation under 35 U.S.C. § 120 of PCT/JP2017/004207, filed Feb. 6, 2017, which is incorporated herein reference and which claimed priority to Japanese Application No. 2016-036774, filed Feb. 29, 2016. The present application likewise claims priority under 35 U.S.C. § 119 to Japanese Application No. 2016-036774, filed Feb. 29, 2016, the entire content of which is also incorporated herein by reference.

### BACKGROUND OF THE INVENTION

### 1. Field of the Invention

The present invention relates to a semiconductor device.

### 2. Description of the Related Art

As substitutions for conventional silicon semiconductor devices, the development of nitride semiconductor devices having the potential to operate at higher speed has been advanced. FIG. 1 is a cross-sectional diagram showing a conventional nitride semiconductor device. A semiconductor device 100R includes an epitaxial substrate 102, interlayer dielectrics 104 and 106, and wiring layers 110, 112, and 114. The semiconductor device 100R is provided with a HEMT (High Electron Mobility Transistor) 200, a thin-film resistor 202, a MIM (Metal-Insulator-Metal) capacitor 204, a GND terminal (pad) 206, and VSS wiring 208 in an integrated manner, which are configured as a high-frequency circuit (MMIC: Monolithic Microwave Integrated Circuit).

In order to provide the HEMT 200 with an improved ground, in some cases, a back-face metal layer 120 is formed on the back face of the epitaxial substrate 102. The wiring layer 110 to be grounded is coupled to the back-face metal layer 120 via a via hole (through hole) 122.

As a result of investigating the conventional technique shown in FIG. 1, the present inventors have come to recognize the following problem. It should be noted that the investigation and understanding described below are by no means within the scope of general common understanding and knowledge of those skilled in this art.

Before formation of the via hole 122, there is a need to provide the epitaxial substrate 102 with an opening by etching (via hole etching). A SiC substrate has high etching resistance. In a case in which an epitaxial substrate 102 having a thickness of 100 μm is etched, this involves an increase of the substrate temperature up to 300° C. to 400° C. Accordingly, as the interlayer dielectrics 104 and 106, there is a need to employ an inorganic material that is not readily damaged due to an increase in the substrate temperature, e.g., a SiN (silicon nitride) film. Alternatively, such an interlayer dielectric is formed as a combination of an air-bridge structure and a SiN film.

However, such a SiN film has a relatively high relative dielectric constant on the order of 7.0. This leads to a difficulty in high-frequency operation in a millimeter-wave region, which is a higher-frequency operation than that in a microwave region. In a case of employing such a SiN film, this leads to a difficulty in forming a multi-layer wiring structure.

### SUMMARY OF THE INVENTION

The present invention has been made in order to solve such a problem. Accordingly, it is an exemplary purpose of an embodiment of the present invention to provide a semiconductor device that is capable of performing a high-speed operation.

An embodiment of the present invention relates to a semiconductor device. The semiconductor device comprises: an epitaxial substrate comprising a SiC (silicon carbide) substrate and a GaN (gallium nitride) epitaxial layer formed on the SiC substrate; a multi-layer wiring structure formed on a front-face side of the epitaxial substrate, and comprising at least one metal wiring layer and an organic interlayer dielectric; a back-face metal layer formed on a back face of the epitaxial substrate; and at least one via hole formed in the epitaxial substrate, and structured to provide a connection between the multi-layer wiring structure and the back-face metal layer.

With this embodiment, by employing a low-k organic interlayer dielectric having a low relative dielectric constant, this arrangement provides high-frequency operation.

Also, via hole etching for forming the via hole may be performed under a condition that does not involve degradation of the interlayer dielectric.

Also, the etching rate may be set to 1 μm/min or less. The cooling temperature applied to a wafer may be 0° C. or less in etching. This arrangement is capable of appropriately suppressing an increase in the substrate temperature in etching, thereby preventing degradation of the interlayer dielectric.

Also, after via hole etching, impurities that have adhered to the epitaxial substrate may be removed by ultrasonic cleaning. This allows a plated layer to be appropriately formed.

Also, the ultrasonic cleaning may be performed in pure water. By employing ultrasonic cleaning using pure water, this method is capable of appropriately removing impurities including NiF (nickel fluoride) as compared with washing using an acid or alkali agent.

Another embodiment of the present invention relates to a manufacturing method for a semiconductor device. The manufacturing method comprises: forming a transistor element on an epitaxial substrate comprising a SiC (silicon carbide) substrate and a GaN (gallium nitride) epitaxial layer formed on the SiC substrate; forming a multi-layer wiring structure comprising at least one metal wiring layer and an organic interlayer dielectric on a front side of the epitaxial substrate; grinding a back face of the epitaxial substrate; performing via hole etching for a back-face side of the epitaxial substrate under a condition that does not involve degradation of the organic interlayer dielectric; and plating the back face of the epitaxial substrate and a side wall of a via hole.

It is to be noted that any arbitrary combination or rearrangement of the above-described structural components and so forth is effective as and encompassed by the present embodiments. Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a cross-sectional diagram showing a conventional nitride semiconductor device;

FIG. 2 is a cross-sectional diagram showing a semiconductor device according to an embodiment; and

FIG. 3A is a cross-sectional diagram showing a via hole formed after acid or alkali washing, and FIG. 3B is a cross-sectional diagram showing a via hole formed after ultrasonic cleaning.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In the present specification, the state represented by the phrase “the member A is coupled to the member B” includes a state in which the member A is indirectly coupled to the member B via another member that does not affect the electric connection therebetween, in addition to a state in which they are physically and directly coupled.

Similarly, the state represented by the phrase “the member C is provided between the member A and the member B” includes a state in which the member A is indirectly coupled to the member C, or the member B is indirectly coupled to the member C via another member that does not affect the electric connection therebetween, in addition to a state in which they are directly coupled.

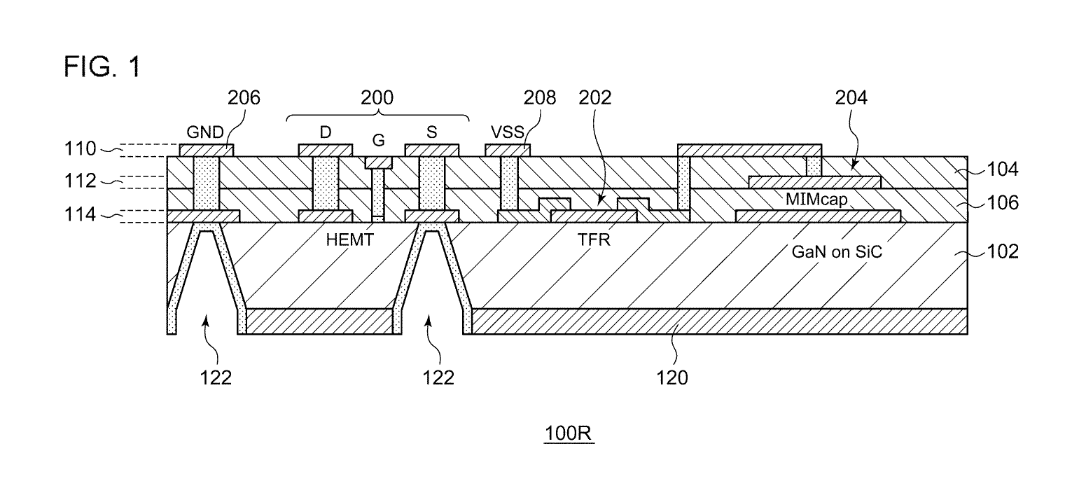

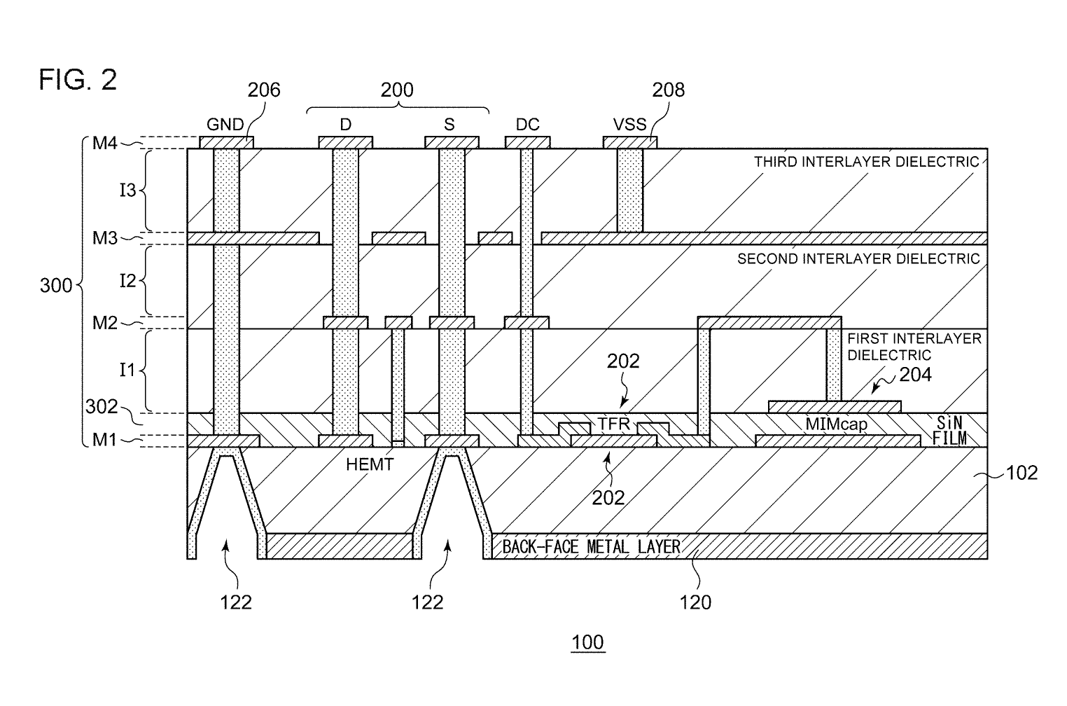

FIG. 2 is a cross-sectional diagram showing a semiconductor device 100 according to an embodiment. As with the configuration shown in FIG. 1, the semiconductor device 100 is provided with a HEMT 200, a thin-film resistor 202, a capacitor 204, a pad 206, wiring 208, and the like, in an integrated manner, which are configured as a MMIC.

The semiconductor device 100 is provided with an epitaxial substrate 102, a multi-layer wiring structure 300, a back-face metal layer 120, and a via hole 122.

The epitaxial substrate 102 includes a SiC (silicon carbide) substrate and a GaN (gallium nitride) epitaxial layer formed on the SiC substrate. The multi-layer wiring structure 300 is formed on the front-face side of the epitaxial substrate 102. The multi-layer wiring structure 300 includes at least one metal wiring layer, i.e., metal wiring layers M1 through M4, and organic interlayer dielectrics I1 through I3. The back-face metal layer 120 is formed on the back face of the epitaxial substrate 102. As a material of such an organic interlayer dielectric, a so-called low-k material having a relative dielectric constant on the order of 2.5 to 3 can be employed, examples of which include polyimide, BCB (benzocyclobutene), fluorine-based resin, and the like. It should be noted that the number of layers of the multi-layer wiring structure 300 is not restricted in particular.

Also, the multi-layer wiring structure 300 may include a protective layer 302 interposed between the interlayer dielectric I1 and the metal wiring layer M1. The protective layer 302 may be formed of SiN (silicon nitride), for example. At least one via hole 122 is formed in the epitaxial substrate 102. Each via hole 122 is configured to provide a connection between the multi-layer wiring structure 300 and the back-face metal layer 120.

With the semiconductor device 100 shown in FIG. 2, the interlayer dielectrics I1 through I3 are formed of a low-k material. This provides the semiconductor device 100 with high-speed operation. Furthermore, this allows the multi-layer wiring structure 300 to have a further increased number of wiring layers according to necessity as compared with conventional techniques employing SiN films.

The above is the basic structure of the semiconductor device 100. Next, description will be made regarding a manufacturing method thereof.

A transistor element (gate, source, and drain) such as a HEMT 200 or the like is formed on the epitaxial substrate 102. Subsequently, the multi-layer wiring structure 300 is formed on the front side of the epitaxial substrate 102. To this point, the manufacturing steps are the same as those in conventional techniques.

Subsequently, the back face of the epitaxial substrate is ground such that it has a substrate thickness of 100 μm. Subsequently, via hole etching is applied to the back-face side of the epitaxial substrate 102 under a condition that does not degrade the organic interlayer dielectrics I1 through I3. The condition that does not degrade the organic interlayer dielectrics may be determined giving consideration to the temperature limit of the material of the organic interlayer dielectric I1 through I3 to be employed, or the like.

As a result of investigation, the present inventors have confirmed that, under a condition that the substrate temperature of the epitaxial substrate 102 is maintained at a reduced temperature of 300° C. or less, via hole opening formation can be performed without the occurrence of degradation (cracking, peeling, discoloration) in the interlayer dielectrics I1 through I3. Also, the substrate temperature of the epitaxial substrate 102 may preferably be maintained at a further reduced temperature of 250° C. or less for added safety.

With typical via hole etching, the typical etching rate is set to 1 μm/min or more. However, with the present embodiment, the etching rate is preferably set to 1 μm/min or less. Specifically, the etching rate is preferably set to a value on the order of 0.5 μm/min to 1 μm/min. This appropriately suppresses heating-up of the epitaxial substrate 102 due to etching, thereby preventing each interlayer dielectric from having a temperature that is higher than the upper temperature limit thereof

In addition to reducing the etching rate, the epitaxial substrate 102 is preferably subjected to thermal cooling to 0° C. or less (e.g., −30° C. to 0° C.). This arrangement is capable of preventing each interlayer dielectric from having a temperature that is higher than the upper temperature limit.

After the completion of etching, the back face of the epitaxial substrate 102 and the side wall of the via hole 122 are plated (e.g., Au (gold) plated). This forms the back-face metal layer 120 and the via hole 122.

As a result of investigation, the present inventors have found that, if impurities adhere to the back face of the epitaxial substrate 102 or the side wall of the via hole 122 before plating, this leads to the occurrence of defects in the plating. In particular, in a case in which the via hole etching is performed using a combination of SF6 which is a typical etching gas and a Ni (nickel) metal mask, this involves the occurrence of NiF (nickel fluoride), which adheres to the back face of the epitaxial substrate 102 or the side wall of the via hole 122.

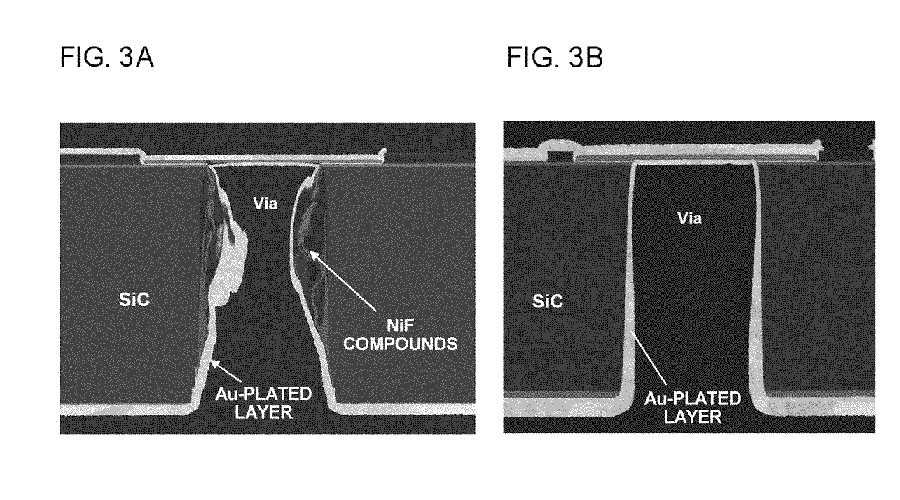

With conventional techniques, typically, such impurities are washed and removed using an acid or alkali agent. However, in a case in which the impurities include NiF (nickel fluoride), in some cases, the impurities cannot be sufficiently removed using such an acid or alkali agent. This leads to a problem in that the Au plating cannot be appropriately performed. Even in a case in which an Au-plated face can be formed, if NiF remains, this leads to a problem. That is to say, if the remaining NiF reacts with water in the air in a high-temperature and high-humidity test for a MMIC or the like, this leads to the formation of water-soluble fluorine compounds, which leads to corrosion of metal wiring or the like in the vicinity of the via hole 122. FIG. 3A is a cross-sectional view of the via hole 122 formed after the washing and removing processing using such an acid or alkali agent.

In order to solve such a problem, in the manufacturing method, the impurities that have adhered to the epitaxial substrate 102 are removed and detached by ultrasonic cleaning. Preferably, the ultrasonic cleaning is performed in pure water at a temperature of 50° C. or more (100° C. or less). FIG. 3B is a cross-sectional view of the via hole 122 formed after the ultrasonic cleaning. By performing such ultrasonic cleaning, this allows the impurities to be removed where they cannot be removed using an acid or alkali agent. This allows a via hole to be appropriately formed.

Furthermore, acid or alkali washing has a problem of the occurrence of damage in the metal wiring. With the present embodiment, ultrasonic cleaning is performed using pure water. Accordingly, the present embodiment provides a so-called damage-free manufacturing method.

It should be noted that, in a case in which the metal mask contains no nickel, and accordingly, in a case in which the impurities contain no NiF, acid or alkali washing may be performed as with conventional techniques.

While the preferred embodiments of the present invention have been described using specific terms, such description is for illustrative purposes only, and it is to be understood that changes and variations may be made without departing from the spirit or scope of the appended claims.

What is claimed is:

1. A semiconductor device comprising:
an epitaxial substrate comprising a SiC (silicon carbide) substrate and a GaN (gallium nitride) epitaxial layer formed on the SiC substrate;
a multi-layer wiring structure formed on a front-face side of the epitaxial substrate, and comprising at least one metal wiring layer and an organic interlayer dielectric;
a back-face metal layer formed on a back face of the epitaxial substrate; and
at least one via hole formed in the epitaxial substrate, and structured to provide a connection between the multi-layer wiring structure and the back-face metal layer.

2. The semiconductor device according to claim 1, wherein via hole etching for forming the via hole is performed under a condition that does not involve degradation of the interlayer dielectric.

3. The semiconductor device according to claim 1, wherein an etching rate is set to 1 μm/min or less.

4. The semiconductor device according to claim 1, wherein a cooling temperature applied to the epitaxial substrate is 0° C. or less in etching.

5. The semiconductor device according to claim 1, wherein, after via hole etching, impurities that have adhered to the epitaxial substrate are removed by ultrasonic cleaning.

6. The semiconductor device according to claim 5, wherein the ultrasonic cleaning is performed in pure water.

7. A manufacturing method for a semiconductor device, comprising:
forming a transistor element on an epitaxial substrate comprising a SiC (silicon carbide) substrate and a GaN (gallium nitride) epitaxial layer formed on the SiC substrate;
forming a multi-layer wiring structure comprising at least one metal wiring layer and an organic interlayer dielectric on a front side of the epitaxial substrate;
grinding a back face of the epitaxial substrate;
performing via hole etching for a back-face side of the epitaxial substrate under a condition that does not involve degradation of the organic interlayer dielectric; and
plating the back face of the epitaxial substrate and a side wall of a via hole.

8. The manufacturing method according to claim 7, further comprising removing, by means of ultrasonic cleaning, impurities that have adhered to the epitaxial substrate.
